(19) United States
(12) Patent Application Publication
(10) Pub. No.: US 2008/0143393 A1
(43) Pub. Date: Jun. 19, 2008

(54) OUTPUT SIGNAL DRIVING CIRCUIT AND METHOD THEREOF

(76) Inventor: Yi-Lin Chen, Taipei City (TW)

Correspondence Address: NORTH AMERICA INTELLECTUAL PROPERTY CORPORATION, P.O. BOX 506, MERRIFIELD, VA, 22116, US

(21) Appl. No.: 11/955,402

(22) Filed: Dec. 13, 2007

(30) Foreign Application Priority Data
Dec. 15, 2006 (TW) 095147099

(51) Int. Cl. H03B 1/00; H03K 3/00

(52) U.S. Cl. 327/108

(57) ABSTRACT

The present invention provides an output signal driving circuit, which includes: a comparator coupled to a reference voltage for comparing the reference voltage and a voltage level of an output terminal to output a comparison signal; a first switch having a terminal coupled to a first supply voltage and having another terminal coupled to an output terminal, wherein the conductivity of the first switch depends on a first input signal and the comparison signal, for selectively conducting the second supply voltage to the output terminal; wherein the first supply voltage is not less than the reference voltage.

### BACKGROUND OF THE INVENTION

1. Field of the Invention

The present invention relates to an output signal driving circuit and method thereof, and more particularly to an output signal driving circuit that utilizes a feedback mechanism for increasing current efficiency while not increasing a supply voltage beyond a predetermined voltage.

2. Description of the Prior Art

A memory bandwidth always dominates the processing performance of a computer system. Therefore, in order to develop a new memory specification, current path technique is becoming an important topic in semiconductor manufacturing. For example, the memory transmission specification of a double data rate memory (DDR Memory) has developed from DDR1, DDR11 to the latest DDR111. However, manufacturers of application specific integrated circuits (ASIC) are unable to provide the latest manufacturing process for clients when the accessing rate of the memory increases. According to the specification validated by JDEC, the DDR1 memory should follow the SSTL25 specification, i.e. the voltage at the input/output (IO) ports must be 2.5 V; the DDR11 memory should follow the SSTL18 specification, i.e. the voltage at the input/output (IO) ports must be 1.8 V, and the DDR111 memory should follow the SSTL15 specification, i.e. the voltage at the input/output (IO) ports must be 1.5 V. However, the ASIC manufacturer only provides two types of manufacturing processes (i.e., low voltage element and high voltage element) for the clients. Therefore, when designing the I/O pads of the memory controller, the high voltage transistor (i.e. 3.3V) is always designed to operate under 2.5V (i.e. DDR1 memory), or the high voltage transistor (i.e. 3.3V) is always designed to operate under 1.8V (i.e. DDR11 memory). Please refer to FIG. 1. FIG. 1 is a diagram illustrating the current-voltage transfer characteristic of the prior art 3.3V transistor. When the 3.3V transistor operates under the voltage of 1.8V (i.e. DDR11), the operating current I₂ is smaller than the operating current I₁, wherein the operating current I₂ is the current of the 3.3V transistor operating under 1.8V and the operating current I₁ is the current of the 3.3V transistor operating under 3.3V. However, the driving current may not be enough to obtain the required charging time of the DDR11 memory at the I/O pads, therefore the width of the transistor should be enlarged to increase the driving current and the area of the I/O pads at the same time. Accordingly, the cost of the chip is increased. Similarly, when the 3.3V transistor operates under 1.5V (i.e. DDR111), the operating current I₃ is smaller than the operating current I₁, wherein the operating current I₃ is the current of the 3.3V transistor operating under 1.5V and the operating current I₁ is the current of the 3.3V transistor operating under 3.3V. It can be seen that the operating current I₃ is smaller than the operating current I₂, thus the required chip area will be larger than the chip area that operates under 1.8V.

### SUMMARY OF THE INVENTION

Therefore, one of the objectives of the present invention is to provide an output signal driving circuit that utilizes a feedback mechanism for increasing the current efficiency while not increasing a supply voltage to beyond a predetermined voltage.

According to an embodiment of the present invention, an output signal driving circuit is disclosed. The output signal driving circuit comprises a comparator, a first switch. The comparator is coupled to a reference voltage for comparing the reference voltage and a voltage level of an output terminal to output a comparison signal. The first switch has a terminal coupled to a first supply voltage, and has another terminal coupled to an output terminal, wherein the conductivity of the first switch depends on a first input signal and the comparison signal, for selectively conducting the second supply voltage to the output terminal; wherein the first supply voltage is not less than the reference voltage.

According to a second embodiment of the present invention, an output signal driving circuit is disclosed. The output signal driving method comprises the steps of: comparing the reference voltage and a voltage level of an output terminal to output a comparison signal; selectively conducting a first supply voltage to the output terminal according to a first input signal and the comparison signal; and selectively conducting a second supply voltage to the output terminal according to a second input signal; wherein the first supply voltage is not less than the reference voltage.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a current-voltage transfer characteristic diagram of the prior art 3.3 V transistor.

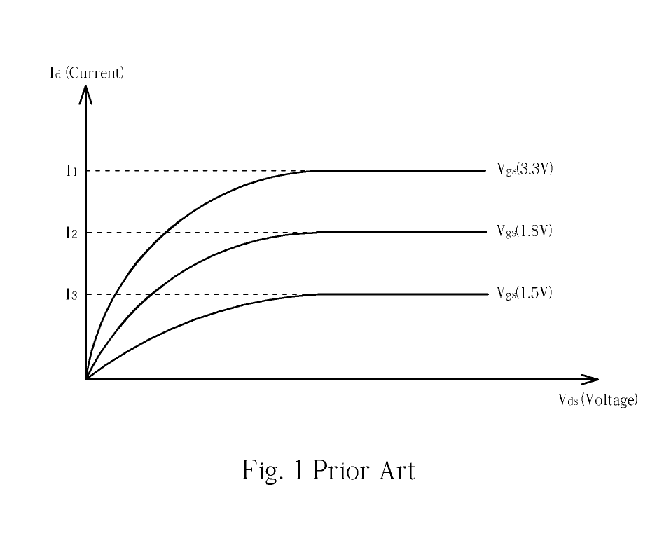

FIG. 2 is a diagram illustrating an output signal driving circuit according to an embodiment of the present invention.

FIG. 3 is a current-voltage transfer characteristic diagram of the P-type field effect transistor as shown in FIG. 2.

FIG. 4 is a current-voltage transfer characteristic diagram of the N-type field effect transistor as shown in FIG. 2.

FIG. 5 is a diagram illustrating an output signal driving method according to a second embodiment of the present invention.

### DETAILED DESCRIPTION

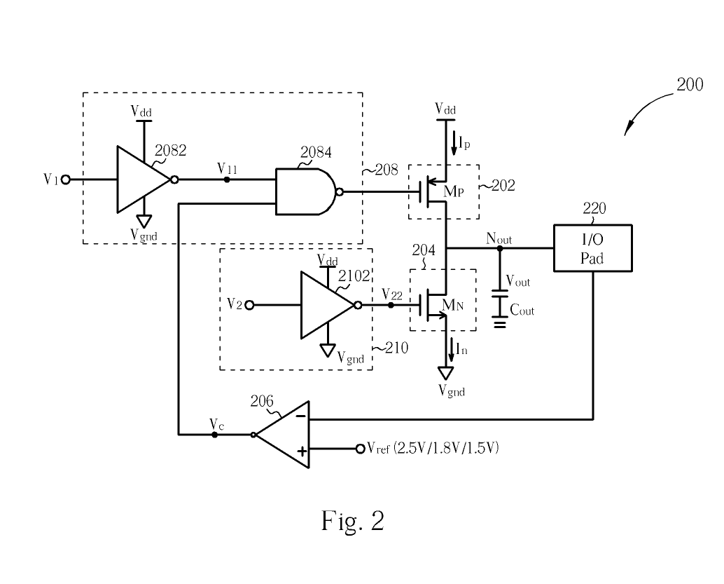

Please refer to FIG. 2. FIG. 2 is a diagram illustrating an output signal driving circuit 200 according to an embodiment of the present invention. The output signal driving circuit 200 includes a first switch 202, a second switch 204, a comparator 206, a first pre-drive circuit 208, and a second pre-drive circuit 210. The first switch 202 has a terminal coupled to a first supply voltage V_{dd}, and has another terminal coupled to an output terminal Nₒᵤₜ. The conductivity of the first switch 202 depends on a first input signal V₁ and a comparison signal. The first switch 202 selectively conducts the first supply voltage V_{dd} to the output terminal Nₒᵤₜ. The second switch 204 has a terminal coupled to a second supply voltage V_{gnd}, and has another terminal coupled to the output terminal Nₒᵤₜ. The conductivity of the second switch 204 depends on a second input signal V₂. The second switch 204 selectively conducts the second supply voltage V_{gnd} to the output terminal Nₒᵤₜ. The comparator 206 is coupled to the output terminal Nₒᵤₜ, and receives a reference voltage V_{ref} for comparing the output voltage Vₒᵤₜ at the output terminal Nₒᵤₜ and the reference voltage V_{ref} to generate a comparison signal V_{c}. The first pre-drive circuit 208 comprises a first buffer unit 2082 and a NAND gate 2084 coupled to the output terminal of the comparator 206 and the control terminal of the first switch 202 respectively, as shown in FIG. 2. The first pre-drive circuit 208 is utilized for controlling the conductivity of the first switch 202 according to the first input signal V₁ and the comparison signal V_{c}. The second pre-drive circuit 210 comprises a second buffer unit 2102 coupled with the second switch 204 for controlling the conductivity of the second switch 204 according to the second input signal V₂ as shown in FIG. 2. The output terminal Nₒᵤₜ of the output signal driving circuit 200 is coupled to an input/output pad 220, which generates an equivalent capacitor Cₒᵤₜ at the output terminal Nₒᵤₜ. In this embodiment, the first switch 202 can be implemented by a P-type field effect transistor M_{P}, the second switch 204 can be implemented by a N-type field effect transistor M_{N}, the first buffer unit 2082 can be implemented by an inverter, and the second buffer unit 2102 can also be implemented by the inverter. Furthermore, for the inverter, the high voltage level is V_{dd} and the low voltage level is V_{gnd}, however, this is not a limitation of the present invention. Those skilled in this art will readily know that there are various implementing methods for the first pre-drive circuit 208 and the second pre-drive circuit 210, thus the detailed description is omitted here for brevity.

Furthermore, in order to describe the operation of the output signal driving circuit 200 more clearly, V_{dd} is set to be 3.3 V, V_{ref} is set to be 2.5 V (i.e. when the output terminal Nₒᵤₜ is coupled to a DDR1 memory) or 1.8V (i.e. when the output terminal Nₒᵤₜ is coupled to a DDR11 memory), or 1.5V (when the output terminal Nₒᵤₜ is coupled to a DDR111 memory), and V_{gnd} is set to be 0 V. If the output signal driving circuit 200 is applied in the DDR1 memory, then V_{ref} is set to be 2.5V, and under the predetermined status, the output voltage Vₒᵤₜ of the output terminal Nₒᵤₜ is 0 V, the first input signal V₁ is 3.3V, and the second input signal V₂ is 0 V, and thus the P-type field effect transistor M_{P} is not conductive, and the N-type field effect transistor M_{N} is conductive. When the first input signal V₁ is switched into the low voltage level 0 V, and the second input signal V₂ is switched into the high voltage level 3.3V at the same time, an output V₂₂ (i.e. the gate terminal of the N-type field effect transistor M_{N}) of the second buffer unit 2102 is switched into the low voltage level 0 V to turn off the second switch 204. Meanwhile, an output V₁₁ of the first buffer unit 2082 is switched into the high voltage level 3.3V, and the comparison signal V_{c} of the comparator 206 is at a high voltage level 3.3V (i.e. V_{ref} is 2.5V and the output voltage Vₒᵤₜ is 0 V), for forcing the output of the NAND gate 2084 to switch into the low voltage level 0 V to turn on the first switch 202. Therefore, a charging current Iₚ is generated, which flows from the first supply voltage V_{dd} to the output terminal Nₒᵤₜ, for charging the equivalent capacitor Cₒᵤₜ.

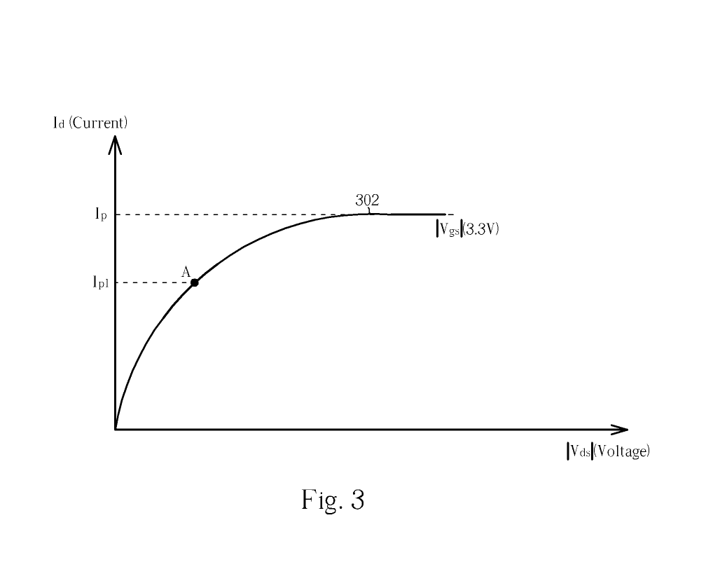

Please refer to FIG. 3. FIG. 3 is a current-voltage transfer characteristic diagram of the P-type field effect transistor M_{P} as shown in FIG. 2. When the output voltage Vₒᵤₜ rises from 0 V to 2.5V, the P-type field effect transistor M_{P}, which can operate under 3.3V, outputs the charging current under the maximum source-gate voltage drop (|V_{gs}|). When the output voltage Vₒᵤₜ increases gradually, the drain-source voltage drop (|V_{ds}|) of the P-type field effect transistor M_{P} decreases gradually, therefore the charging current outputted by the P-type field effect transistor M_{P} also decreases gradually along the direction of the curve 302, and stops at the point A as shown in FIG. 3. Please note that the point A represents that the output voltage Vₒᵤₜ reaches 2.5V, meanwhile the charging current is Iₚ₁. When the output voltage Vₒᵤₜ reaches 2.5V, the comparison signal V_{c} of the comparator 206 is switched to a low voltage level 0 V, and thus the output of the NAND gate 2084 is then switched into a high voltage level 3.3V to turn off the first switch 303. Finally, the charging current Iₚ stops charging the equivalent capacitor Cₒᵤₜ and the output voltage Vₒᵤₜ can be kept at (or approach) 2.5 V.

Then, if the output voltage Vₒᵤₜ at the output terminal Nₒᵤₜ should be switched into 0 V, the P-type field effect transistor M_{P} has to be in a non-conducting state and the N-type field effect transistor M_{N} has to be in a conducting state in order to discharge the equivalent capacitor Cₒᵤₜ, and then decrease the currently output voltage Vₒᵤₜ (2.5V). Therefore, the first input signal V, is switched to the high voltage level 3.3V, and the second input signal V₂ is switched to the low voltage level 0 V to turn on the second switch 204. Meanwhile, an output V₁₁ of the first buffer unit 2082 is switched into the low voltage level 0 V, and the comparison signal V_{c} of the comparator 206 is at the low voltage level 0 V (i.e. V_{ref} is 2.5V and the output voltage Vₒᵤₜ approaches or is higher than 2.5V) for forcing the output of the NAND gate 2084 to be higher than 3.3V in order to turn off the first switch 202. Therefore, a discharging current Iₙ is generated by the N-type field effect transistor M_{N}, for charging the equivalent capacitor Cₒᵤₜ at the output terminal Nₒᵤₜ. Furthermore, when the output voltage Vₒᵤₜ decreases from 2.5V, the comparison signal V_{c} of the comparator 206 is switched from the low voltage level 0 V to the high voltage level 3.3V at the time when the output voltage Vₒᵤₜ is lower than the reference voltage V_{ref}. However, as the output of the first buffer unit 2082 is still kept at the low voltage level 0 V, the changing of the voltage level of the comparison signal V_{c} does not affect the output of the NAND gate 2084, which means that the P-type field effect transistor M_{P} can remain non-conductive.

If the output signal V₁₁ (i.e. the buffered signal) is at the low voltage level 0 V, the compared output V_{c} is at the low voltage level 0 V and the output V₂₂ (i.e. the buffered signal) is at the low voltage level 0 V; if the output signal V₁₁ (i.e. the buffered signal) is at the low voltage level 0 V, the compared output V_{c} is at the high voltage level 3.3V and the output V₂₂ (i.e. the buffered signal) is at the low voltage level 0 V; or if the output signal V₁₁ (i.e. the buffered signal) is at the high voltage level 3.3V, the compared output V_{c} is at the low voltage level 0 V and the output V₂₂ (i.e. the buffered signal) is at the low voltage level 0 V; then the output terminal Nₒᵤₜ will receive an external signal from a next stage circuit.

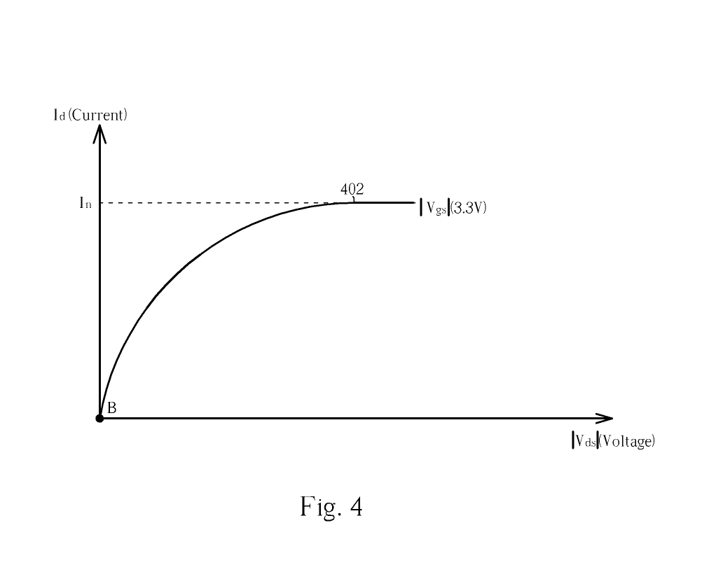

Please refer to FIG. 4. FIG. 4 is a current-voltage transfer characteristic diagram of the N-type field effect transistor M_{N} as shown in FIG. 2. When the output voltage Vₒᵤₜ decreases from 2.5V to 0 V, the N-type field effect transistor M_{N} Outputs the discharging current Iₙ under the maximum source-gate voltage drop (|V_{gs}|). When the output voltage Vₒᵤₜ decreases gradually, the drain-source voltage drop (|V_{ds}|) of the N-type field effect transistor M_{N} decreases gradually, therefore the discharging current outputted by the N-type field effect transistor M_{N} also decreases gradually along the direction of the curve 402, and stops at the point B as shown in FIG. 4. Please note that the point B represents that the output voltage Vₒᵤₜ reaches 0 V, meanwhile the discharging current is zero.

Please note that the operation of the above-mentioned output signal driving circuit 200 is described by being applied in the DDR1 memory, however the output terminal Nₒᵤₜ of the output signal driving circuit 200 can also be coupled to the DDR11 memory of the DDR111 memory, in which the corresponding operation is almost the same as the above-mentioned embodiment, but the V_{ref} is set to be 1.8V or 1.5V, thus the detailed description is omitted here for brevity. Furthermore, the above-mentioned embodiments of the present invention can be applied in the DDR1, DDR11, and DDR111 memories implemented by only one manufacturing process. On the other hand, the transistor breakdown phenomenon will not occur in the P-type and N-type field effect transistors M_{P}, M_{N} of the embodiment of the present invention.

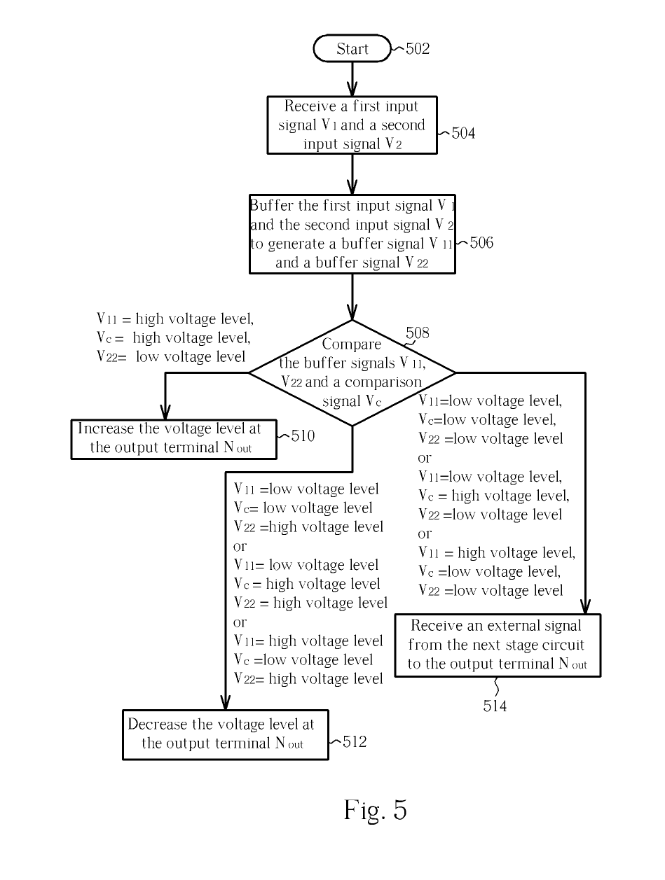

Please refer to FIG. 5. FIG. 5 is a diagram illustrating an output signal driving method according to an embodiment of the present invention. The output signal driving method can be applied in the embodiment output signal driving circuit 200 of the present invention. The output signal driving method includes the steps of:

Step 502: Start;

Step 504: Receive a first input signal V₁ and a second input signal V₂:

Step 506: Buffer the first input signal V₁ and the second input signal V₂ to generate a buffer signal V₁₁ and a buffer signal V₂₂;

Step 508: Compare the buffer signals V₁₁, V₂₂ and a comparison signal V_{c}, if the buffer signal V₁₁ is at the high voltage level, the comparison signal V_{c} is at the high voltage level and the buffer signal V₂₂ is at the low voltage level, then go to step 510; if the buffer signal V₁₁ is at the low voltage level, the comparison signal V_{c} is at the low voltage level and the buffer signal V₂₂ is at the high voltage level, or if the buffer signal V₁₁ is at the low voltage level, the comparison signal V_{c} is at the high voltage level and the buffer signal V₂₂ is at the high voltage level, or if the buffer signal V₁₁ is at the high voltage level, the comparison signal V_{c} is at the low voltage level and the buffer signal V₂₂ is at the high voltage level, then go to step 512; and if the buffer signal V₁₁ is at the low voltage level, the comparison signal V_{c} is at the low voltage level and the buffer signal V₂₂ is at the low voltage level, or if the buffer signal V₁₁ is at the low voltage level, the comparison signal V_{c} is at the high voltage level and the buffer signal V₂₂ is at the low voltage level, or if the buffer signal V₁₁ is at the high voltage level, the comparison signal V_{c} is at the low voltage level and the buffer signal V₂₂ is at the low voltage level, then go to step 514;

Step 510: Conduct the first supply voltage V_{dd} to the output terminal Nₒᵤₜ and open the path between the second supply voltage V_{gnd} and the output terminal Nₒᵤₜ to increase the voltage level at the output terminal Nₒᵤₜ;

Step 512: Open the path between the first supply voltage V_{dd} and the output terminal Nₒᵤₜ and conduct the second supply voltage V_{gnd} to the output terminal Nₒᵤₜ to decrease the voltage level at the output terminal Nₒᵤₜ; and

Step 514: Open the path between the first supply voltage V_{dd} and the output terminal Nₒᵤₜ and open the path between the second supply voltage V_{gnd} to the output terminal Nₒᵤₜ to receive an external signal from the next stage circuit to the output terminal Nₒᵤₜ.

The output signal driving method of the present invention receives the first input signal V₁ and the second input signal V₂ in step 504, and then buffers the first input signal V₁ and the second input signal V₂ to generate the buffer signals V₁₁, V₂₂ respectively in step 503. In step 508, the output signal driving method compares the buffer signals V₁₁, V₂₂ and the comparison signal V_{c} to determine the voltage variation at the output terminal Nₒᵤₜ.

Accordingly, the apparatus and method of the present invention utilize feedback circuit or feedback mechanism to conduct or open the related conducting path when the feedback voltage at the output terminal is higher or lower than a reference voltage, for increasing the current efficiency while not increasing the voltage to beyond a predetermined voltage, wherein the reference voltage is determined according to the predetermined voltage.

Those skilled in the art will readily observe that numerous modifications and alterations of the device and method may be made while retaining the teachings of the invention.

What is claimed is:

1. An output signal driving circuit, comprising:
a comparator, coupled to a reference voltage, for comparing the reference voltage and a voltage level of an output terminal to output a comparison signal;
a first switch, having a terminal coupled to a first supply voltage, and having another terminal coupled to an output terminal, wherein the conductivity of the first switch depends on a first input signal and the comparison signal, for selectively conducting the first supply voltage to the output terminal; and
a second switch, having a terminal coupled to the output terminal and having another terminal coupled to a second supply voltage wherein the conductivity of the second switch depends on a second input signal, for selectively conducting the second supply voltage to the output terminal;
wherein the first supply voltage is not less than the reference voltage.

2. The output signal driving circuit of claim 1, further comprising:
a first pre-drive circuit, coupled to the comparator and the first switch, for receiving the first input signal to control the conductivity of the first switch according to the first input signal and the comparison signal.

3. The output signal driving circuit of claim 2, wherein the first pre-drive circuit comprises:
a logic gate, for performing a specific logical calculation upon the comparison signal to generate a first control signal, and the first control signal is outputted to the first switch for controlling the conductivity of the first switch.

4. The output signal driving circuit of claim 2, wherein the first pre-drive circuit comprises:
a buffer unit, for buffering the first input signal.

5. The output signal driving circuit of claim 1, further comprising:
a second pre-drive circuit, for receiving the second input signal, and controlling the conductivity of the second switch according to the second input signal.

6. The output signal driving circuit of claim 5, wherein the second pre-drive circuit comprises:
a buffer unit, for buffering the second input signal.

7. The output signal driving circuit of claim 3, wherein the logic gate is a NAND gate.

8. The output signal driving circuit of claim 4, wherein the buffer unit comprises at least an inverter.

9. The output signal driving circuit of claim 6, wherein the buffer unit comprises at least an inverter.

10. The output signal driving circuit of claim 1, wherein the first switch is a P-type field effect transistor and the second switch is a N-type field effect transistor.

11. The output signal driving circuit of claim 1, being installed within a memory.

12. The output signal driving circuit of claim 11, wherein the memory is a double data rate memory.

13. The output signal driving circuit of claim 1, wherein the first supply voltage is 3.3V, and the reference voltage is one of 2.5V, 1.8V, and 1.5V.

14. An output signal driving method, comprising:
(a) comparing a reference voltage and a voltage level of an output terminal to output a comparison signal;
(b) selectively conducting a first supply voltage to the output terminal according to a first input signal and the comparison signal; and
(c) selectively conducting a second supply voltage to the output terminal according to a second input signal;
wherein the first supply voltage is not less than the reference voltage.

15. The output signal driving method of claim 14, wherein the step (b) comprises:
inverting the first input signal to generate an inverted signal; and
performing a NAND operation upon the inverted signal and the comparison signal.

16. The output signal driving method of claim 14, wherein the step (c) comprises:
inverting the second input signal.

17. The output signal driving method of claim 14, being applied in a memory.

18. The output signal driving method of claim 14, wherein the first supply voltage is 3.3 V, and the reference voltage is one of 2.5 V, 1.8 V, and 1.5 V.
